(19) United States
(12) Patent Application Publication
(10) Pub. No.: US 2017/0271072 A1
(43) Pub. Date: Sep. 21, 2017

(54) COVER AND ELECTRONIC DEVICE INCLUDING THE SAME

(71) Applicant: SAMSUNG ELECTRO-MECHANICS CO., LTD., Suwon-si (KR)

(72) Inventors: Chang Hee LEE, Suwon-si (KR); Hee Seung KIM, Suwon-si (KR); Jae Sun WON, Suwon-si (KR)

(73) Assignee: SAMSUNG ELECTRO-MECHANICS CO., LTD., Suwon-si (KR)

(21) Appl. No.: 15/298,740

(22) Filed: Oct. 20, 2016

(30) Foreign Application Priority Data
Mar. 15, 2016 (KR) 10-2016-0030866
May 17, 2016 (KR) 10-2016-0060324
Jun. 17, 2016 (KR) 10-2016-0075708

(51) Int. Cl. H01F 27/28; H01F 38/14; H05K 5/04; H05K 5/03; H01F 27/06; H01F 27/32

(52) U.S. Cl. CPC H01F 27/2804; H01F 27/06; H01F 27/2885; H01F 27/32; H05K 5/04; H05K 5/03; H01F 38/14; H01F 2027/065

(57) ABSTRACT

A cover and an electronic device are described including the same. The cover includes a center area, a slit, and an inductance part. The center area is disposed on a plate of the cover. The slit is connected to the center area. The inductance part surrounds the center area defined by the slit.

### CROSS-REFERENCE TO RELATED APPLICATION(S)

This application claims benefit under 35 USC 119(a) of priority to Korean Patent Application Nos. 10-2016-0030866 filed on Mar. 15, 2016, 10-2016-0060324 filed on May 17, 2016 and 10-2016-0075708 filed on Jun. 17, 2016 in the Korean Intellectual Property Office, the disclosures of which are incorporated herein by reference in their entirety.

### BACKGROUND

1. Field

The following description relates to a cover and an electronic device including the cover.

2. Description of Related Art

Wireless transfer technology has been widely applied to a variety of electronic devices including various communications/portable terminals, such as smartphones and wearable devices.

As part of a design, such electronic devices commonly include a metal case as a cover thereof. However, in a case in which the cover of the electronic device is formed of a metal, an Eddy current or a Foucault current may occur due to wirelessly transferred electromagnetic waves, and current loss may occur due to the Eddy current.

Depending on the degree of current loss, a coupling coefficient of a wireless transfer system may be degraded, and wireless transfer efficiency or charging efficiency may be significantly degraded.

Further, the current loss due to the Eddy current creates a hot spot, which may cause a problem in that the radiation of heat may be difficult.

### SUMMARY

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

In accordance with an embodiment, there is provided a cover, including: a center area disposed on a plate of the cover; a slit connected to the center area; and an inductance part surrounding the center area defined by the slit.

The center area may be disposed to correspond to a center of a winding of a coil.

The inductance part may have a shape wound to be adjacent to an outer circumference of the center area.

The inductance part may have a terminal to connect the inductance part to a coil.

The slit may separate the inductance part from the conductive plate.

The center area may be filled with an insulating member.

The center area may include metal tiles.

The center area may further include an insulating member provided in spaces between the metal tiles.

In accordance with an embodiment, there is provided an apparatus, including: a coil configured to supply power to a device body; and a cover configured to cover one side of the coil and including a center area disposed on a conductive plate, a slit including an end connected to the center area, and an inductance part surrounding the center area defined by the slit and connected to the coil to form an inductance.

The center area may be disposed to correspond to a center a winding of the coil.

The inductance part may have a shape wound to be adjacent to an outer circumference of the center area.

The slit may separate the inductance part from the conductive plate.

The coil may include a first wiring and a second wiring, and both ends of the inductance part may be connected to one end of the first wiring and one end of the second wiring, respectively.

The center area may be filled with an insulating member.

The center area may include metal tiles.

The center area may further include an insulating member provided in spaces between the metal tiles.

In accordance with an embodiment, there is provided a cover of an electronic device, including: a center area including an opening at a center of a plate of the cover that corresponds to a center of a coil wiring; an inductance part disposed adjacent to an outer circumference of the center area; and a slit configured to extend from the center area and spiral at a distance from and around the center area and including a gap forming a boundary between the inductance part and the plate to separate the inductance part from a main portion of the plate.

The center area may be filled with non-metallic material.

The center area may be supported by an insulating member and may include metal tiles including either one or both of a lattice form and a radial arrangement.

The inductance part may include at least one terminal to connect the inductance part to one end of the coil wiring for wireless transfer.

Other features and aspects will be apparent from the following detailed description, the drawings, and the claims.

### BRIEF DESCRIPTION OF DRAWINGS

FIG. 1 is a perspective view illustrating an example of a cover, according to an embodiment;

FIG. 2 is an exploded perspective view schematically illustrating an example of an electronic device;

FIG. 3 is an equivalent circuit diagram of an example of a wireless power transfer system including the cover, according to an embodiment;

FIGS. 4A through 4C are plan views illustrating various shapes of an inductance part included in the cover, according to an embodiment;

FIG. 5 is a plan view illustrating an example of an inductance part, according to an embodiment;

FIG. 6 is a perspective view illustrating an example of a connection between a cover and a coil wiring, according to an embodiment;

FIG. 7 is a plan view illustrating an example of a cover, according to an embodiment;

FIG. 8 is a plan view illustrating an example of a cover, according to an embodiment;

FIG. 9 is a plan view illustrating an example of a cover, according to an embodiment; and

FIGS. 10A through 10E are plan views illustrating various shapes of metal tiles.

Throughout the drawings and the detailed description, the same reference numerals refer to the same elements. The drawings may not be to scale, and the relative size, proportions, and depiction of elements in the drawings may be exaggerated for clarity, illustration, and convenience.

### DETAILED DESCRIPTION

The following detailed description is provided to assist the reader in gaining a comprehensive understanding of the methods, apparatuses, and/or systems described herein. However, various changes, modifications, and equivalents of the methods, apparatuses, and/or systems described herein will be apparent after an understanding of the disclosure of this application. For example, the sequences of operations described herein are merely examples, and are not limited to those set forth herein, but may be changed as will be apparent after an understanding of the disclosure of this application, with the exception of operations necessarily occurring in a certain order. Also, descriptions of features that are known in the art may be omitted for increased clarity and conciseness.

The features described herein may be embodied in different forms, and are not to be construed as being limited to the examples described herein. Rather, the examples described herein have been provided merely to illustrate some of the many possible ways of implementing the methods, apparatuses, and/or systems described herein that will be apparent after an understanding of the disclosure of this application.

Throughout the specification, when an element, such as a layer, region, or substrate, is described as being “on,” “connected to,” or “coupled to” another element, it may be directly “on,” “connected to,” or “coupled to” the other element, or there may be one or more other elements intervening therebetween. In contrast, when an element is described as being “directly on,” “directly connected to,” or “directly coupled to” another element, there can be no other elements intervening therebetween.

As used herein, the term “and/or” includes any one and any combination of any two or more of the associated listed items.

Although terms such as “first,” “second,” and “third” may be used herein to describe various members, components, regions, layers, or sections, these members, components, regions, layers, or sections are not to be limited by these terms. Rather, these terms are only used to distinguish one member, component, region, layer, or section from another member, component, region, layer, or section. Thus, a first member, component, region, layer, or section referred to in examples described herein may also be referred to as a second member, component, region, layer, or section without departing from the teachings of the examples.

The terminology used herein is for describing various examples only, and is not to be used to limit the disclosure. The articles “a,” “an,” and “the” are intended to include the plural forms as well, unless the context clearly indicates otherwise. The terms “comprises,” “includes,” and “has” specify the presence of stated features, numbers, operations, members, elements, and/or combinations thereof, but do not preclude the presence or addition of one or more other features, numbers, operations, members, elements, and/or combinations thereof.

Due to manufacturing techniques and/or tolerances, variations of the shapes shown in the drawings may occur. Thus, the examples described herein are not limited to the specific shapes shown in the drawings, but include changes in shape that occur during manufacturing.

The features of the examples described herein may be combined in various ways as will be apparent after an understanding of the disclosure of this application. Further, although the examples described herein have a variety of configurations, other configurations are possible as will be apparent after an understanding of the disclosure of this application.

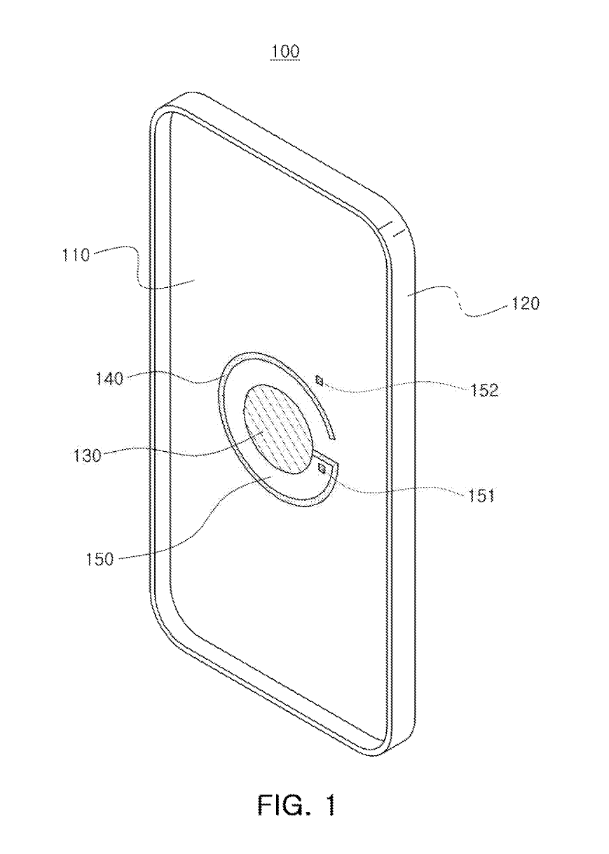

FIG. 1 is a perspective view illustrating an example of a cover, in accordance with an embodiment.

Referring to FIG. 1, a cover 100 is formed from or includes a plate 110. The plate 110 is formed of, for example, a conductive material such as an aluminum alloy, a magnesium alloy, a copper alloy, or other similar type of alloy. Accordingly, the cover 100, a metal case of an electronic device, is coupled to a body of an electrical device. Further, the cover 100 may be separate or removable from the body of the electrical device. As a non-exhaustive example only, the electrical device as described herein may be a mobile device, such as a cellular phone, a smart phone, a wearable smart device (such as a ring, a watch, a pair of glasses, a bracelet, an ankle bracelet, a belt, a necklace, an earring, a headband, a helmet, or a device embedded in clothing), a portable personal computer (PC) (such as a laptop, a notebook, a subnotebook, a netbook, or an ultra-mobile PC (UMPC), a tablet PC (tablet), a phablet, a personal digital assistant (PDA), a digital camera, a portable game console, an MP3 player, a portable/personal multimedia player (PMP), a handheld e-book, a global positioning system (GPS) navigation device, or a sensor, or a stationary device, such as a desktop PC, a high-definition television (HDTV), a DVD player, a Blu-ray player, a set-top box, or a home appliance, or any other mobile or stationary device configured to perform wireless or network communication. In one example, a wearable device is a device that is designed to be mountable directly on the body of the user, such as a pair of glasses or a bracelet. In another example, a wearable device is any device that is mounted on the body of the user using an attaching device, such as a smart phone or a tablet attached to the arm of a user using an armband, or hung around the neck of the user using a lanyard.

Further, a protection layer 120 is formed on a surface of the plate 110. The protection layer 120 protrudes from the surface of the plate 110 and surrounds the plate 110. The protection layer 120 may be formed by anodizing one surface of the plate 110. Alternatively, the protection layer 120 may be formed of an insulating film such as polyethylene terephthalate (PET), polycarbonate (PC), polyethersulfone (PES), polyimide (PI), polymethlymethacrylate (PMMA), cyclo-olefin polymers (COP), or other similar material. However, the material of the protection layer 120 is not limited thereto.

The cover 100 includes a slit 140 and an inductance part 150. In addition, the cover 100 includes a center area 130.

In an example, an inductor is disposed inside of or on top of the cover 100, and is a wireless transmission coil that receives a current to generate an electromagnetic field. Alternatively, the inductor is a wireless reception coil that receives the electromagnetic field to induce a voltage.

The center area 130 is disposed in an area corresponding to a center of a winding of the inductor disposed inside of or on top of the cover 100 as the cover 100 is coupled to the electronic device. In one embodiment, the center area 130, is an opening and is formed in a various shapes such as a polygonal shape including a circular shape and a quadrangular shape, and other similar shapes, and the inductance part 150 is adjacent to an outer circumference of the center area 130. In addition, the center area 130 exposes the inside of the cover through the opening, and may also be filled with a non-metallic material to shield the inside and an outside of the cover from each other.

To improve wireless transfer efficiency, the center area 130 needs to significantly reduce loss of magnetic flux passing through the center area 130. That is, because the center area 130 is positioned between the wireless transmission coil and the wireless reception coil, it is desired to significantly reduce interference on a magnetic coupling between the coils by the center area 130.

To this end, the center area 130 exposes the inside of the cover 100 through the opening formed by a cut or a perforation through the plate 110 at the center area 130, and may also be filled with the non-metallic material to physically shield the inside of the cover from the outside thereof.

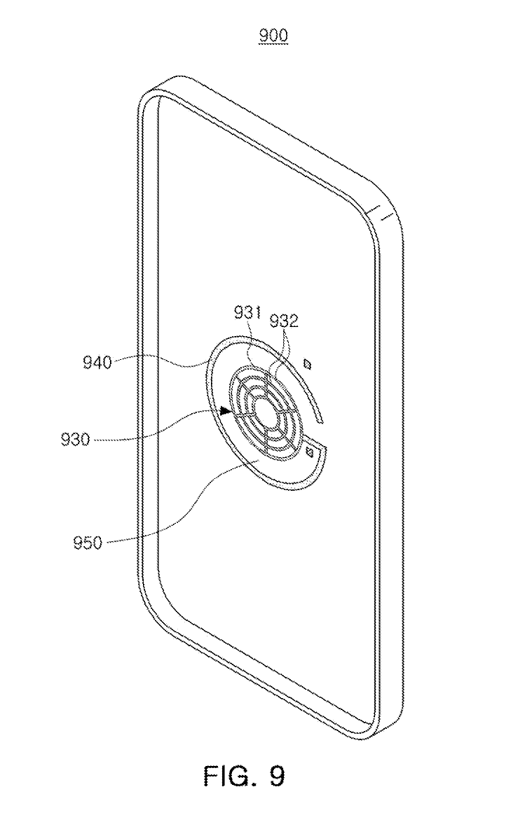

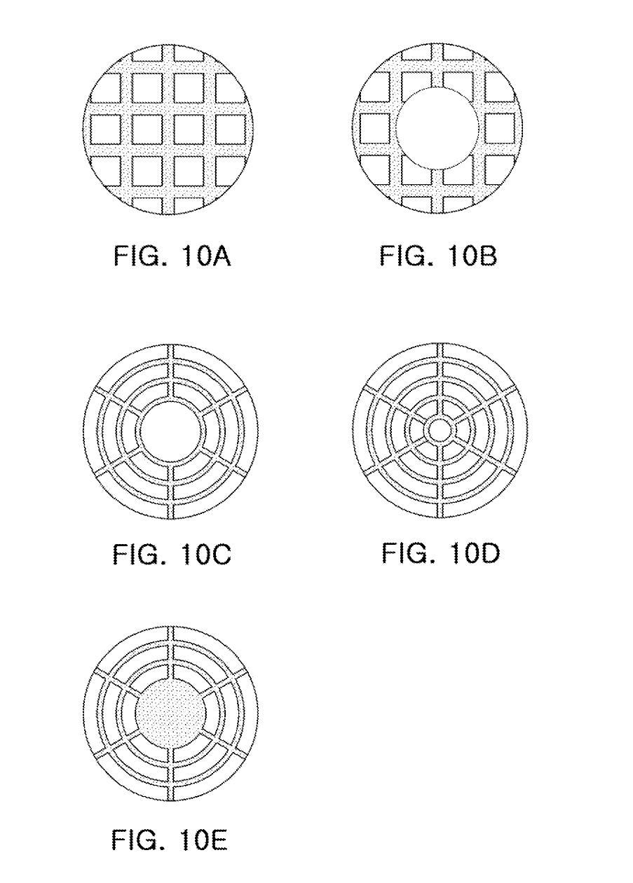

Alternatively, the center area 130 includes a plurality of metal tiles supported by an insulating member. The center area 130 including the plurality of metal tiles will be described in more detail with reference to FIGS. 9 and 10.

As shown in FIG. 1, the slit 140 forms a boundary between the plate 110 and the inductance part 150. That is, the slit 140 may be formed by cutting one area of the plate 110, and the inductance part 150 separated from the plate 110 by the slit 140 may be formed. In addition, the slit 140 may be extended from the center area 130 and coil or spiral at a distance from and around the center area 130.

Further, the center area 130 and the slit 140 may be formed by a press processing method, for example, a punching molding method, but are not limited thereto.

The inductance part 150 is disposed on an area of the cover 100 that is separated by the slit 140 from a main portion of the plate 110. The slit 140 separates the inductance part 150 from the main portion of the plate 110. Further, in a case in which the cover 100 includes the center area 130, the inductance part 150 is disposed on an area of the cover 100 that is between the center area 130 and a main portion of the plate 110, adjacent to the outer circumference of the center area 130, and with a shape surrounding the center area 130.

In addition, the inductance part 150 may be disposed on an area corresponding to the inductor disposed or positioned inside of the cover 100, and one end of the inductance part 150 is connected to the plate 110.

The inductance part 150 may have the same material as the plate 110, but for the purpose of wireless transfer efficiency, a surface of the inductance part 150 may be covered with a conductive member, or the material of the inductance part 150 may be modified by other processing methods.

In addition, the inductance part 150 may have at least one terminal to electrically connect the inductance part 150 to one end of the coil.

Although FIG. 1 illustrates a case in which a first terminal 151 is disposed at one end of the inductance part 150 and second terminal 152 is disposed on the plate 110, outside the inductance part 150, the second terminal 152 may be disposed on the inductance part 150. For example, the second terminal 152 may be disposed at a proximity to the other end of the inductance part 150 at which the inductance part 150 is connected to the plate 110.

That is, in the case in which the inductance part 150 is connected to the plate 110, a position of the second terminal 152 may be changed to be at the other end of the inductance part 150 or to be on the plate 110 to connect with a coil substrate on which the device body or the coil is formed.

Furthermore, the insulating member may be provided to cover or form on the slit 140 and the center area 130. The insulating member may be an electrical insulating material such as silicon, or other insulating material. That is, the insulating member may be filled in a space formed by the slit 140 and the center area 130, and as a result, permeation of a foreign material into the inside of the cover 100 may be prevented.

In addition, the insulating member may have the same color as the plate 110 so that the slit 140 and the center area 130 do not appear different from the plate 110 in appearance.

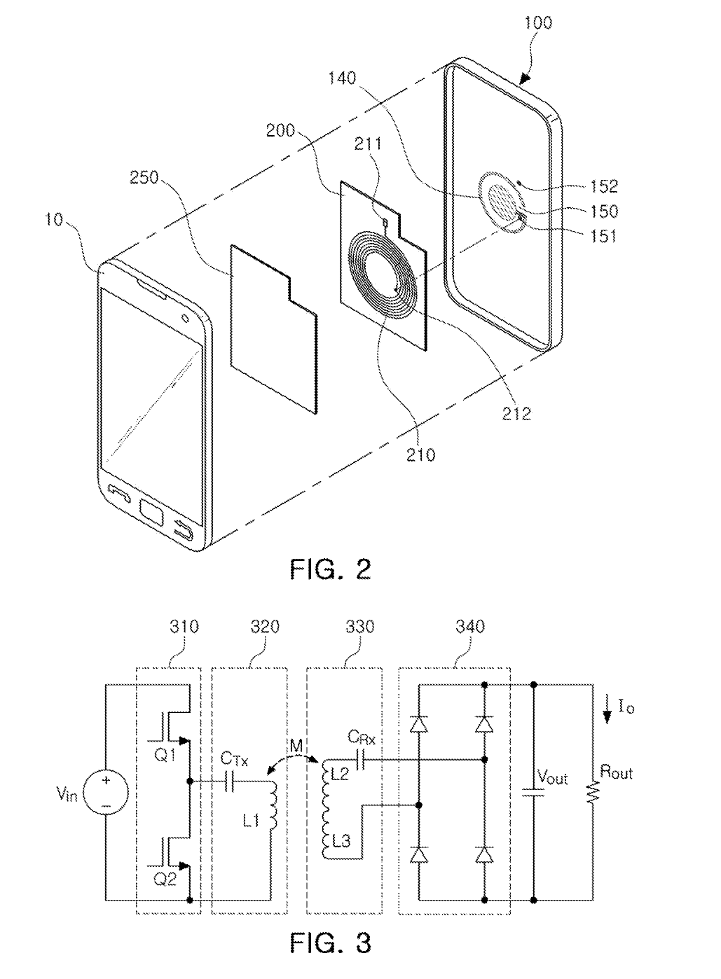

FIG. 2 is an exploded perspective view schematically illustrating an example of an electronic device, in accordance with an embodiment. Although FIG. 2 illustrates a case in which a portable terminal is assumed as an example of the electronic device, the electronic device is not limited thereto. For example, as long as the electronic device is a portable electronic device such as a tablet, a notebook, a wearable device, and an electronic device forming a wireless transfer system together with the portable electronic device, this electronic device may be the electronic device according to an embodiment.

Referring to FIG. 2, the electronic device includes the device body 10, the cover 100, and a coil substrate 200.

Further, the electronic device includes a shielding sheet 250.

The coil substrate 200 is disposed in or within the electronic device, and includes a coil wiring 210 formed on the coil substrate 200 as an example of the inductor for wireless transfer. The coil substrate 200, a thin film substrate, may be, for example, a flexible board such as a flexible printed circuit board (FPCB). However, the coil substrate 200 is not limited thereto.

The coil wiring 210, a transmitting or receiving coil for wireless transfer, may be formed in a form or a shape of a circuit wiring on at least any one surface of the coil substrate 200. For example, the coil may be a wireless power receiving coil for wirelessly receiving power, and may be a wireless communications coil of a near field communication (NFC) type, a magnetic secure transmission (MST) type using wirelessly transferred electromagnetic waves.

The coil wiring 210 may be formed in a spiral shape or a loop shape on a surface of the coil substrate 200 or an inner plane thereof, and includes a contact pad 211 formed at one end thereof. The contact pad 211 electrically connects the coil wiring 210 to the device body 10.

Although the embodiment describes a case in which the coil wiring 210 is generally formed in a circular spiral shape by way of example, the shape of the coil wiring 210 is not limited thereto, and may be variously applied. For example, the coil wiring 210 may be formed in a polygonal shape including a quadrangular shape. In addition, a winding direction of the coil wiring 210 may be selected for a magnetic coupling between transmitting and receiving coils of the coil wiring 210.

An insulating protection layer (not illustrated) to protect the coil wiring 210 from the outside may be formed on one surface of the coil wiring 210, as needed.

The shielding sheet 250 is disposed or positioned on one side of the coil substrate 200. In one example, the shielding sheet 250 is provided to efficiently form a magnetic path for an electromagnetic field generated by wireless power electromagnetic waves from a charger. In an alternative configuration, although the shielding sheet 250 is shown on one side of the coil substrate 200, a shielding sheet 250 may be disposed or positioned on both sides of the coil substrate 200.

To this end, the shielding sheet 250 may be formed in a flat plate shape (or a sheet shape), and may be formed of a magnetic sheet such as a ferrite sheet, or a metal sheet such as aluminum. However, the shielding sheet 250 is not limited thereto.

Further, the shielding sheet 250 is not limited to the above-mentioned configuration, and may be variously applied. For example, the shielding sheet 250 may be formed by applying ferrite powder particles or conductive powder particles to one surface of the coil substrate 200. In an alternative configuration, the shielding sheet 250 may be formed by applying the ferrite powder particles or the conductive powder particles to both surfaces of the coil substrate 200.

The cover 100, a metal case of the portable terminal, may be coupled to the device body, as illustrated in FIG. 1. In addition, the cover 100 may be coupled to the device body 10 to complete the electronic device, and may be a battery cover able to be separated from the device body 10 when a battery is replaced.

The cover 100 includes the center area 130, the slit 140 (FIG. 1), and the inductance part 150. The center area 130 is formed in an area corresponding to a center of a winding of the coil, and the inductance part 150 has a shape wound to be adjacent to the outer circumference of the center area 130. In addition, the inductance part 150 has a shape corresponding to the coil wiring 210, and is formed in an area corresponding to the coil wiring 210.

In addition, the inductance part 150 includes at least one terminal 151 and 152 to connect the inductance part 150 to one end of the coil wiring 210. For example, the first terminal 151 is disposed in one end of the inductance part 150, and is connected to a connection terminal 212 of the coil wiring 210. In an example, a contact pad 211 electrically connecting the coil wiring 210 to the device body 10 is disposed at one end of the coil wiring 210, and the connection terminal 212 to electrically connect the coil wiring 210 to the inductance part 150 is disposed at another end of the coil wiring 210.

By the above-mentioned connection, the coil wiring 210 may be electrically connected to the inductance part 150.

The inductance part 150 is spaced apart from the plate 110 (FIG. 1) while having the slit 140 as a gap (FIG. 1) to enable separation from the plate 110. Accordingly, in a case in which wirelessly transferred electromagnetic waves pass through the inductance part 150, a formation of a closed loop of an Eddy current may be prevented, and current loss caused by the Eddy current may be significantly reduced.

In addition, because the inductance part 150 is electrically connected to the coil wiring 210 to form constant inductance together with the coil wiring 210 and to function as a single coil, wireless transfer efficiency is improved.

FIG. 3 is an equivalent circuit diagram of an example of a wireless power transfer system including the cover 100, in accordance with an embodiment.

The wireless power transfer system includes a power supply 310, a transmitting stage 320, a receiving stage 330, and a rectifier 340.

The power supply 310 may receive supply power Vᵢₙ. In addition, a first switch Q1 and a second switch Q2 of the power supply 310 may configure a half-bridge circuit. Although FIG. 3 illustrates the half-bridge circuit by way of example, the power supply 310 may be implemented as a full-bride circuit or in various other circuit forms. The first and second switches Q1 and Q2 alternatively perform an ON/OFF switching operation and convert the supply power Vᵢₙ into alternating current (AC) power.

The transmitting stage 320 includes a transmission capacitor C_{Tx} and a first coil L1. The transmission capacitor C_{Tx} and the first coil L1 form a resonance circuit. The resonance circuit of the transmitting stage 320 includes the AC power from the power supply 310 supplied thereto to form an electromagnetic field.

The receiving stage 330 includes a second coil L2 and a third coil L3. The second coil L2 corresponds to the inductor disposed inside of the cover 100, and the third coil L3 may correspond to the inductance part 150 (FIG. 1) of the cover 100. In addition, the second and third coils L2 and L3 are connected to each other in series to form constant inductance. Although in one embodiment the second coil L2 and the third coil L3 are connected to each other in series as one element, the second coil L2 or the third coil L3 may be separated into two or more circuits so as to be electrically connected to each other.

In addition, the receiving stage 330 further includes a reception capacitor C_{Rx}. The reception capacitor C_{Rx}, and the second and third coils L2 and L3 form a resonance circuit. In addition, the second coil L2, the third coil, and the reception capacitor C_{Rx} are connected to each other in series.

When the power is wirelessly transferred, the first coil L1 of the transmitting stage 320, and the second and third coils L2 and L3 of the receiving stage 330 are magnetically coupled to each other. The transmitting stage 320 applies the AC power to the first coil L1 to form the electromagnetic field, and the electromagnetic field induces a voltage to the receiving coil in the receiving stage 330.

Because a resonance frequency of the resonance circuit is determined by values of inductance and capacitance, the resonance circuit of the receiving stage 330 may have a constant resonance frequency by inductance formed by the second coil L2 and the third coil L3, and capacitance of the reception capacitor C_{Rx}. Efficiency of wireless power transfer is significantly increased when the receiving stage 330 has a resonance frequency corresponding to the electromagnetic field generated from the transmitting stage 320. Therefore, the capacitance of the reception capacitor C_{Rx}, and the inductance of the second and third coils L2 and L3 are selected by considering the resonance circuit of the transmitting stage 320.

The rectifier 340 may rectify the voltage induced to the receiving stage 330 and convert the rectified voltage into a direct current (DC) voltage, and may also step the DC voltage up or down. The DC voltage may be used to supply the power to the electronic device or charge the battery.

In addition, the efficiency of the wireless power transfer may depend on a coupling coefficient K and a quality coefficient Q between the inductors.

The coupling coefficient K is determined by a distance between the inductors, a ratio (D2/D1) of a diameter D2 of the receiving coil to a diameter D1 of the transmitting coil, shapes of the coils, and an angle between the coils.

In a case in which the first coil is formed on the cover, because the distance between the inductors is decreased, the coupling coefficient K increases and the power transfer efficiency improves.

In addition, the received voltage may have a predetermined relationship with inductance, increased depending on the number of windings (number of turns) of the inductor. That is, the receiving coil has a constant inductance to produce a voltage required by the receiving stage.

As described above, because the second coil L2 corresponding to the inductor (for instance, the coil wiring 210) disposed inside of the cover 100 and the third coil L3 corresponding to the inductance part 150 (FIG. 1) of the cover 100 may form the inductance, the inductor may be miniaturized by adopting the inductance part.

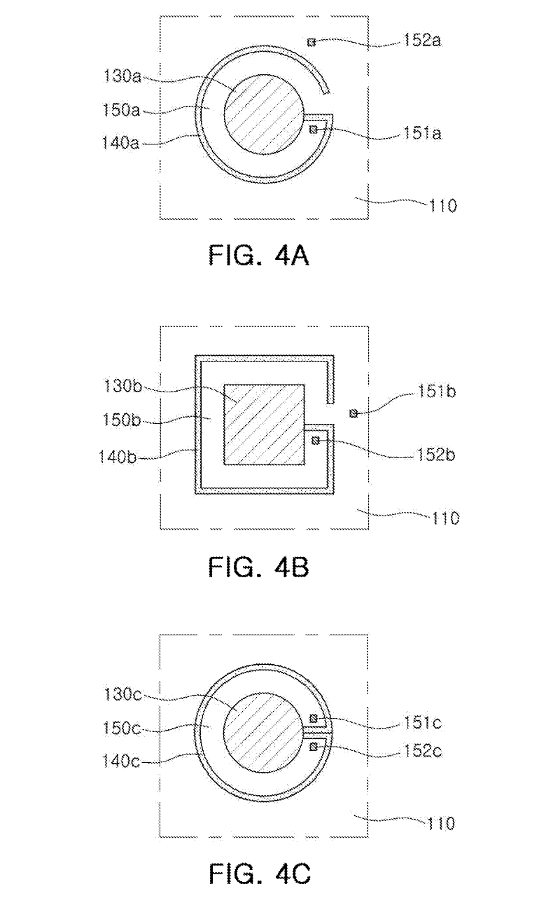

FIGS. 4A through 4C are plan views illustrating various shapes included in a portion of the cover 100, in accordance with an embodiment.

Referring to FIG. 4A, the cover 100 includes a plate 110 onto which a circular center area 130a, a circular inductance part 150a surrounding the center area 130a, and a slit 140a formed on an outer circumference of the inductance part 150a are formed. In addition, a first terminal 151a is disposed at one end of the inductance part 150a, and a second terminal 152a is disposed outside of the slit 140a.

Referring to FIG. 4B, the plate 110 a quadrangular center area 130b, an inductance part 150b, and a slit 140b. In addition, a first terminal 152b is formed at one end of the inductance part 150b, and a second terminal 151b is disposed at various positions outside of the slit 140b.

Referring to FIG. 4B, the plate 110 includes a slit 140c that completely separates the plate 110 and an inductance part 150c from each other. The slit 140c is formed to surround an outer circumference of the inductance part 150c and electrically insulates the plate 110 (FIG. 1) and the inductance part 150c from each other.

In this embodiment, a second terminal 151c is disposed at the other end of the inductance part 150c to connect the inductance part 150c to the device body or the coil.

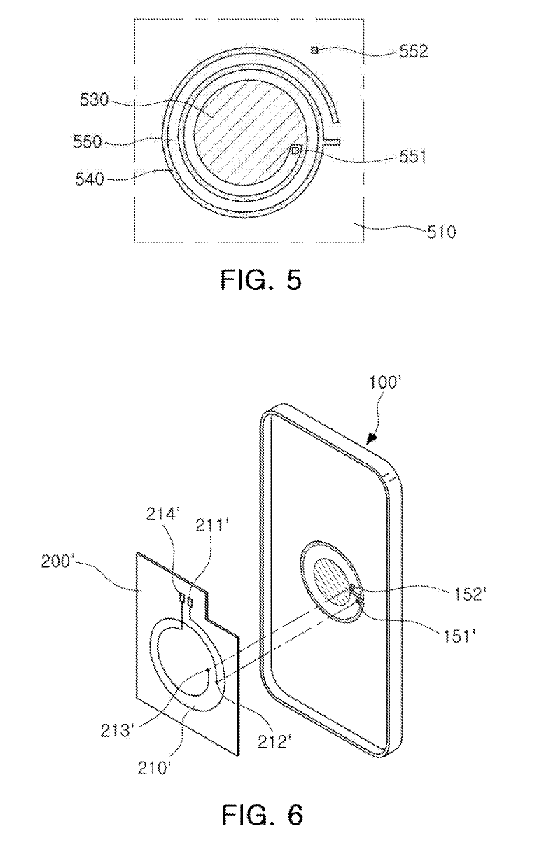

FIG. 5 is a plan view illustrating an example of an inductance part 550, in accordance with an embodiment.

Referring to FIG. 5, the plate 510 of the cover includes an inductance part 550 having a spiral shape that the inductance part 550 is wound two or more times. To this end, the slit 540 has a spiral shape that the slit 540 is wound once or more, similar to the inductance part 550.

FIG. 6 is a perspective view illustrating an example of a connection between a cover 100′ and a coil wiring 210′, in accordance with an embodiment.

A coil substrate 200′ includes first and second contact pads 211′ and 214′ to electrically connect a coil wiring 210′ to the device body. In addition, the coil substrate 200′ includes first and second connection terminals 212′ and 213′ to connect the coil wiring 210′ to both ends of an inductance part formed on a cover 100′.

For example, the coil wiring 210′ includes first and second wirings, and both ends of the inductance part are connected to one end of each of the first and second wirings through the first and second contact pads 211′ and 214′.

That is, the first and second connection terminals 212′ and 213′ each is connected to first and second terminals 151′ and 152′ disposed in the inductance part.

Accordingly, the inductance part forms a single coil together with or integral with the coil wiring 210′.

Because other configurations and functions may be understood from the configuration and function described above in FIG. 2, a detailed description thereof will be omitted.

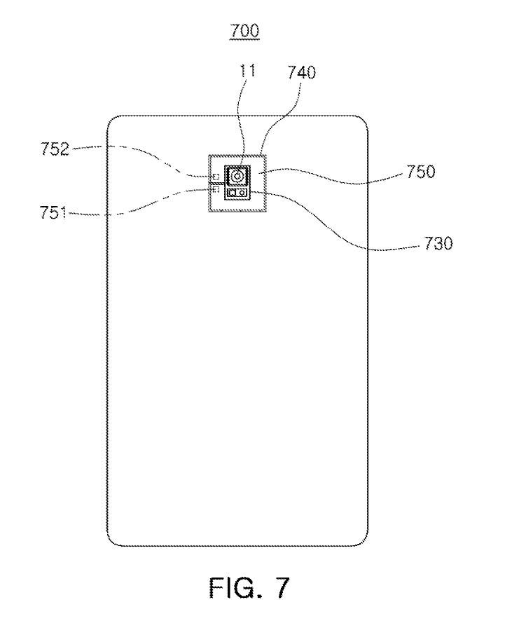

FIG. 7 is a plan view illustrating an example of a cover 700, in accordance with an embodiment.

As illustrated in FIG. 7, a camera lens installed in the device body is exposed through a center area 730, an opening formed in the cover 700.

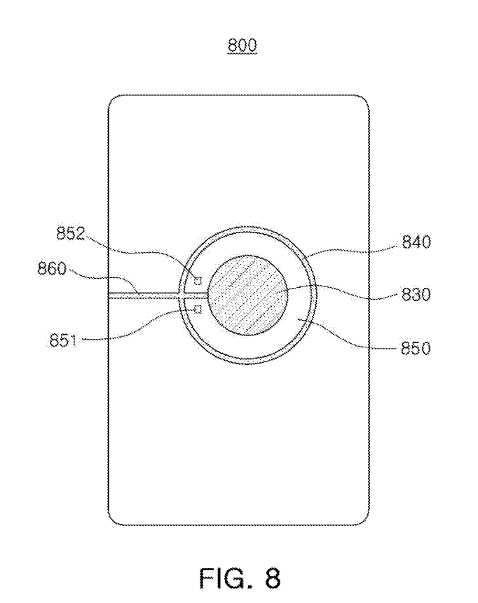

FIG. 8 is a plan view illustrating an example of a cover 800, in accordance with an embodiment.

Referring to FIG. 8, the cover 800 includes a slit surrounding an outer circumference of an inductance part 850 and extended to an edge of the cover 800. For example, the slit includes a first slit 840 surrounding the inductance part 850, and a second slit 860 extending to the edge of the cover 800 and connecting the first slit 840 to an exterior of the cover 800.

FIG. 9 is a plan view illustrating an example of a cover, and FIGS. 10A through 10E are plan views illustrating various shapes of a plurality of metal tiles.

Referring to FIG. 9, a cover 900 includes a center area 930, and the center area 930 includes a plurality of metal tiles 931.

Further, an insulating member 932 is filled between the plurality of metal tiles 931 and in an outer space of the plurality of metal tiles 931. That is, the insulating member 932 is filled inside gaps between the plurality of metal tiles 931.

The plurality of metal tiles 931 include the same material as the plate 110 (FIG. 1), but are not limited thereto.

The insulating member 932 may be an electrical insulating material, and may have adhesive properties. For example, the insulating member 932 may be formed of a material such as polyethylene terephthalate (PET), polyimide (PI), polycarbonate (PC), polyethersulfone (PES), cyclo-olefin polymers (COP), polymethlymethacrylate (PMMA), or the like. However, the material of the insulating member 932 is not limited thereto.

The insulating member 932 may include a first member and a second member. As described above, the first member is formed in or within the gaps, which are the spaces between the plurality of metal tiles 931. Although not illustrated in the drawings, the second member covers one surface of the plurality of metal tiles 931. For example, the second member is attached as a film so as to be coated on one surface of the plurality of metal tiles 931 or to cover one surface of the plurality of metal tiles 931. Accordingly, the second member protects and supports the plurality of metal tiles 931.

As such, because the cover 900 has the center area 930 formed by the plurality of metal tiles, current loss by an Eddy current is significantly reduced. Therefore, absorption loss in which the magnetic flux generated from the wireless transmission coil is absorbed into the center area 930 and is converted to thermal energy is significantly reduced.

Referring to FIGS. 10A through 10E, the plurality of metal tiles may have various shapes.

The plurality of metal tiles may be arranged in a lattice form in the center area as illustrated in FIG. 10A, and may include an opening as illustrated in FIG. 10B.

Further, as illustrated in FIGS. 10C and 10D, the plurality of metal tiles may be radially arranged.

Further, as illustrated in FIG. 10E, the plurality of metal tiles may be radially arranged, and the opening may be filled with the insulating member.

As set forth above, according to various embodiments, the cover and the electronic including the same significantly reduce the current loss by the Eddy current and improve the wireless transfer efficiency.

While this disclosure includes specific examples, it will be apparent after an understanding of the disclosure of this application that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner, and/or replaced or supplemented by other components or their equivalents. Therefore, the scope of the disclosure is defined not by the detailed description, but by the claims and their equivalents, and all variations within the scope of the claims and their equivalents are to be construed as being included in the disclosure.

What is claimed is:

1. A cover, comprising:
a center area disposed on a conductive plate of the cover;
a slit connected to the center area; and
an inductance part surrounding the center area defined by the slit.

2. The cover of claim 1, wherein the center area is disposed to correspond to a center of a winding of a coil.

3. The cover of claim 1, wherein the inductance part has a shape wound to be adjacent to an outer circumference of the center area.

4. The cover of claim 1, wherein the inductance part has a terminal to connect the inductance part to a coil.

5. The cover of claim 1, wherein the slit separates the inductance part from the conductive plate.

6. The cover of claim 1, wherein the center area is filled with an insulating member.

7. The cover of claim 1, wherein the center area comprises metal tiles.

8. The cover of claim 7, wherein the center area further comprises an insulating member provided in spaces between the metal tiles.

9. An apparatus, comprising:
a coil configured to supply power to a device body; and
a cover configured to cover one side of the coil and comprising
a center area disposed on a conductive plate,
a slit comprising an end connected to the center area, and
an inductance part surrounding the center area defined by the slit and connected to the coil to form an inductance.

10. The apparatus of claim 9, wherein the center area is disposed to correspond to a center a winding of the coil.

11. The apparatus of claim 9, wherein the inductance part has a shape wound to be adjacent to an outer circumference of the center area.

12. The apparatus of claim 9, wherein the slit separates the inductance part from the conductive plate.

13. The apparatus of claim 9, wherein the coil comprises a first wiring and a second wiring, and
both ends of the inductance part are connected to one end of the first wiring and one end of the second wiring, respectively.

14. The apparatus of claim 9, wherein the center area is filled with an insulating member.

15. The apparatus of claim 9, wherein the center area comprises metal tiles.

16. The apparatus of claim 15, wherein the center area further comprises an insulating member provided in spaces between the metal tiles.

17. A cover of an electronic device, comprising:
a center area comprising an opening at a center of a conductive plate of the cover that corresponds to a center of a coil wiring;
an inductance part disposed adjacent to an outer circumference of the center area; and
a slit configured to extend from the center area and spiral at a distance from and around the center area and comprising a gap forming a boundary between the inductance part and the plate to separate the inductance part from a main portion of the plate.

18. The cover of claim 17, wherein the center area is filled with non-metallic material.

19. The cover of claim 17, wherein the center area is supported by an insulating member and comprises metal tiles comprising either one or both of a lattice form and a radial arrangement.

20. The cover of claim 17, wherein the inductance part comprises at least one terminal to connect the inductance part to one end of the coil wiring for wireless transfer.
